(19) United States
(12) Patent Application Publication
(10) Pub. No.: US 2009/0066348 A1
(43) Pub. Date: Mar. 12, 2009

(54) Apparatus and method for quantitative determination of target molecules

(76) Inventors: Young Shik Shin, Pasadena, CA (US); Michael Amori, Pasadena, CA (US); Yuri Bunimovich, Williamsville, NY (US); James H. Heath, South Pasadena, GA (US)

Correspondence Address: Steinfl & Bruno, 301 N Lake Ave Ste 810, Pasadena, CA, 91101, US

(21) Appl. No.: 11/897,159

(22) Filed: Aug. 29, 2007

Related U.S. Application Data
(60) Provisional application No. 60/824,750, filed on Sep. 6, 2006.

(51) Int. Cl. G01R 27/08

(52) U.S. Cl. 324/693; 977/953

(57) ABSTRACT

A nanoelectronic device for detecting target molecules is described. The device has an array of nanoscale wires serving as sensors of target molecules and electrical contacts, electrically contacting the nanowires at end regions of the nanoscale wires. The end regions are covered with an insulating material. The insulating material also defines a window region of the nanoscale wires, not covered by the insulating material. Probe molecules are located on the nanoscale wires along the window region. A microfluidic channel can also be provided, to allow flow of the target molecules. A method of fabricating the nanoelectronic device is also shown and described.

### CROSS REFERENCE TO RELATED APPLICATIONS

This application claims priority to U.S. Provisional Application entitled “A Nanodevice for the Label-free, Absolute Quantitation of Biomolecule Concentrations and Kinetic binding Parameters” filed on Sep. 7, 2006 Application Ser. No. 60/842,750, Docket number CIT-4725, the disclosure of which is incorporated herein by reference in its entirety.

### STATEMENT OF GOVERNMENT GRANT

The U.S. Government has certain rights in this disclosure pursuant to Grant No. CA 119347 awarded by the National Cancer Institute at Frederick.

### TECHNICAL FIELD

The present disclosure relates to determination of molecules. In particular, it refers to an apparatus and method for quantitative determination of target biomolecules.

### BACKGROUND

Over the past few years a number of new biomolecular sensors have been reported [References 1-5]. The development of these devices is in part driven by the emerging needs of both systems biology [References 6, 7] and personalized and predictive medicine [Reference 8]—both of which are increasingly requiring quantitative, rapid, and multiparameter measurement capabilities on ever smaller amounts of tissues, cells, serum, etc. To meet these needs, many groups have focused their attention on developing real time, highly sensitive and potentially scalable tools for detecting nucleic acids and proteins. One-dimensional nanostructures such as nanotubes [References 9-11], semiconductor [References 12, 13], metal oxide nanowires (NWs)[Reference 14], and conducting polymer nanofilaments [Reference 15] have all been shown as capable of the label-free detection of small molecules, nucleic acids, and proteins.

Silicon nanowire (SiNW) biosensors are promising label-free, electronic-based detectors of biomolecules [Reference 2]. However, significant scientific challenges remain before SiNW sensors can be viewed as a realistic technology.

One challenge relates to the use of these devices in biologically relevant media, which is typically a 0.14M electrolyte. NW sensors detect the local change in charge density (and the accompanying change in local chemical potential) that characterizes a target/capture agent binding event. That changing chemical potential is detected as a ‘gating’ voltage by the NW, and so, at a given voltage, affects the source (S)→drain (D) current value, or I_{SD}. However, that change is screened (via Debye screening) from, the NW by the solution in which the sensing takes place [Reference 16]. Debye screening is a function of electrolyte concentration, and in a 0.14M electrolyte (which represents physiological environments such as serum) the screening length is about 1 nm [Reference 17]. Because of this, all reports on SiNW sensors for proteins or DNA have been carried out in low ionic strength solutions [References 12, 13 and 18].

A second challenge involves showing reproducible and high-throughput nanofabrication methods that can produce nearly identical NW sensors time and time again, and that allow for multiple measurements to be executed in parallel. Dimensional arguments [Reference 20] imply that that the fabrication of highly sensitive NW sensors requires non-traditional fabrication methods [References 21, 22]. To date, all reports of NW sensors have utilized semiconductor NWs grown as bulk materials [Reference 23] using the vapor-liquid-solid (VLS) technique [Reference 24]. This method produces high quality NWs, but they are characterized by a distribution of lengths and diameters, and they also must be assembled into the appropriate device structure (or the device structure must be constructed around the nanowire [Reference 25]).

A third challenge involves the SiNW surface. The effectiveness of SiNWs for biomolecular sensing arises in part because of their high surface-to-volume ratio. The native (1-2 nm thick) surface oxide on a SiNW may limit sensor performance due to the presence of interfacial electronic states [References 28, 29]. In addition, the oxide surface of SiNWs acts as a dielectric which can screen the NW from the chemical event to be sensed. Covalent alkyl passivation of Si(111) surfaces can render those surfaces resistant to oxidation in air [Reference 30] and under oxidative potentials [Reference 31]. Recently, methyl passivated SiNWs were shown to exhibit improved field-effect transistor characteristics [Reference 32]. More complex molecules, such as amine terminated alkyl groups, can be covalently attached to H-terminated Si surfaces (including SiNWs) via UV-initiated radical chemistry [References 33-36]. Such chemistry has been used for the covalent attachment of DNA to VLS grown SiNWs [Reference 37]. DNA may also be immobilized on amine-terminated surfaces via electrostatic interactions.

A final challenge is actually an opportunity that is provided by the intrinsic nature of a label free, real time sensor. The standard such sensing technique is surface plasmon resonance (SPR) [Reference 38]. SPR is utilized to determine the kₒₙ and k_{off} rates, and hence the equilibrium binding affinities, of complementary DNA strands, protein-antibody binding, etc. The capture agent (e.g. single stranded DNA) is typically surface-bound, and so the key experimental variables are the analyte (complementary strand) concentration and time. If kₒₙ and k_{off} are both known, then SPR can be utilized to quantitate the analyte concentration. Very few biomolecular sensing techniques are quantitative.

In summary, knowledge of the absolute molar concentration of certain molecules such as biomolecules would provide for useful information for problems ranging from fundamental biological problems to clinical in vitro diagnostics of health and disease.

In particular, many molecules, and in particular biomolecules, are characterized by complementary molecules, and the molecule is often called the “target”, while the complementary molecule is called the “probe”. For example, the complement to a specific protein (the target) is a specific antibody (the probe), and the complement to a single-stranded oligomer of DNA (the target) is the complementary oligomer strand of DNA (the probe).

The interactions between two complementary molecules are described by an equilibrium binding constant K_{A}=kₒₙ/k_{off} where kₒₙ and k_{off} are the on and off rates of target/probe binding. For many biological measurement procedures, the probe molecule is attached to the surface of some substrate, such as a glass slide. If a probe molecule is attached onto a surface, and that surface is placed into a solution containing the target molecules, then target molecules will bind to some fraction C of the target molecules in solution. Under certain experimental conditions, the rate at which the target biomolecules bind to the probe molecules is only determined by kₒₙ, k_{off} and C. kₒₙ and k_{off} are typically independent of C.

Thus, if the rate of target/probe binding can be directly measured, at various known values of C, then kₒₙ and k_{off} can be separately determined. Conversely, if kₒₙ and k_{off} are known for a given target/probe pair of molecules and in particular biomolecules, then C can be determined.

The most common method for determining some or all of the constants kₒₙ, k_{off} and C is a technique known as Surface Plasmon Resonance (SPR). At target concentrations below a few tens of nanoMolar of target molecule, SPR is usually not sufficiently sensitive to be used for an accurate determination of any of the various constants. Most molecules are present in tissues or bloods at concentrations that are substantially less than 10 nanoMolar. Thus, SPR can not be used to determine most of the biomolecule concentration is <10 nanoMolar.

### SUMMARY

According to a first aspect of the present disclosure, a nanoelectronic device for detecting target molecules is provided, comprising: an array of nanowires serving as sensors of target molecules, the nanowires comprising i) electrically contacted regions at their ends, the electrically contacted regions being covered with an insulating material and ii) a central window region coated with a probe molecule; and a microfluidics channel placed across the array of silicon nanowires, the microfluidics channel adapted to direct a flow of solution containing the target molecules.

According to a second aspect of the present disclosure, a method for quantitatively determine a molar concentration of a target molecule is provided, comprising: providing an array of nanowires; electrically contacting the nanowires at their ends; depositing an insulating layer over the nanowires; forming a window in the insulating layer along a region of the nanowires different from an electrically contacted region of the nanowires; treating the surface of the nanowires for later contact with probe molecules along the region different from an electrically contacted region; placing a microfluidic channel across the array of nanowires; introducing a solution containing the probe molecules into the microfluidic channel, the solution reacting with the treated surface of the nanowires; directing a flow of solution containing the target molecule in the microfluidic channel; monitoring electrical resistance of the nanoscale wires to record change in resistance of the nanoscale wires over time at two different values of target molecule concentration to determine an on rate kₒₙ and an off rate k_{off} of target-probe binding; and introducing a solution containing the target molecule at an unknown molar concentration to quantitatively determine the molar concentration of the target molecule.

According to a third aspect, a method of fabricating a nanoelectronic device is disclosed, comprising: providing a silicon-on-insulator substrate; patterning a top silicon layer of the silicon-on-insulator substrate to obtain nanoscale wires; adding electrical contacts to the nanoscale wires; depositing an insulating layer on the nanoscale wires and the electrical contacts; and opening a window in the insulating layer to define a sensing area of the nanoscale wires.

According to a fourth aspect, a nanoelectronic device for detecting target molecules is disclosed, comprising: an array of nanoscale wires serving as sensors of target molecules; electrical contacts, electrically contacting the nanowires at end regions of the nanoscale wires; an insulating material covering the end regions of the nanoscale wires and defining a window region of the nanoscale wires, the window region of the nanoscale wires not being covered by the insulating material; and probe molecules, located on the nanoscale wires along the window region.

According to some embodiments, the present disclosure describes a nanoelectronic device that, when coupled with microfluidic devices, and operated in a certain fashion (described in the detailed description below), can measure kₒₙ and k_{off} for a particular target/probe combination, and C, the concentration of the target molecule. The apparatus, methods and systems of the present disclosure can be extended to lower concentrations of target molecules and in particular of target biomolecules, that can be measured by competing techniques, and can thus be extended into clinically relevant concentration ranges of biomolecules.

According to some embodiments, the nanoelectronic device is comprised of an array of nanowires (e.g., 5 to 10 silicon nanowires each of about 10-20 nm wide and a few micrometers long). The nanowires serve as the sensors of the target biomolecules, and the doping level and nature of the dopant atoms within the nanowires determines the sensitivity limits and concentration ranges over which the nanowire sensors can operate. The silicon nanowires are electrically contacted at either end, and the portion of the nanowires that are electrically contacted is covered with an insulating material. A microfluidics channel is then placed across the nanowires for directing the flow of solution containing the target biomolecules of interest. The central region of the nanowires in between the electrical contacts is coated with the probe molecule. When the solution containing the target molecule is flown over the nanowire sensors, a change in resistance, as a function of time, is recorded by monitoring the electrical resistance of the nanowires. If measurements are done at two different values of target molecule concentration C, then the plots of time-dependent change in resistance can be utilized to determine kₒₙ and k_{off} values for target/probe binding. Once kₒₙ and k_{off} are known, then a solution containing the target biomolecule at an unknown concentration is introduced, and the concentration of the target molecule may be quantitatively determined.

According to some embodiments, the devices, methods and systems of the present disclosure are based on the ability of a single-stranded complementary oligonucleotide to significantly change the conductance of a group of 20 nm diameter SiNWs (p-doped at ˜10¹⁹ cm⁻³) in 0.165M solution by hybridizing to a primary DNA strand that has been electrostatically adsorbed onto an amine terminated organic monolayer atop the NWs. This intimate contact of the primary strand with the amine groups of the NW surface brings the binding event close enough to the NW to be electronically detected. In addition, within a 0.165M ionic strength solution the DNA hybridization is more efficient [References 10, 19].

According to some embodiments, in the devices methods and systems herein disclosed the Superlattice Nanowire Pattern Transfer (SNAP) method [Reference 26] is used to produce highly aligned array of 400 SiNWs, each 20 nm wide and ˜2 millimeters long. Standard nano and microfabrication techniques are utilized to control the NW doping level [Reference 27], to section the NWs into several individual sensor arrays, to establish electrical contacts to the NW sensors, and to integrate each array into a microfluidic channel. The resulting NWs exhibit excellent, controllable, and reproducible electrical characteristics from device-to-device and across fabrication runs. The sensor platforms may also be fabricated in reasonably high throughput.

According to some embodiments, in the methods and systems of the present disclosure the NW sensors are doped so that their sensing dynamic range is optimized to match that of SPR for the detection of DNA hybridization. The equivalence of these two methods, is shown and thus the use of SiNW sensors for quantitating analyte concentrations. SiNW sensors can be optimized for significantly higher sensitivity than SPR, and thus can potentially be utilized to quantitate the concentrations of specific biomolecules at very low concentrations. That provides a unique application of these devices.

According to some embodiments of the present disclosure, the applicants explore how the characteristics of SiNW sensors vary as the nature of the inorganic/organic interface is varied. The applicants have found that SiNW sensors in which the native oxide provides the interface for organic functionalization are significantly inferior in terms of both sensitivity and dynamic range when compared with SiNW sensors that are directly passivated with an alkyl monolayer.

The details of one or more embodiments of the disclosure are set forth in the accompanying drawings and the description below. Other features, objects, and advantages will be apparent from the description and drawings, and from the claims.

### BRIEF DESCRIPTION OF THE DRAWINGS

The accompanying drawings, which are incorporated into and constitute a part of this specification, illustrate one or more embodiments of the present disclosure and, together with the detailed description, serve to explain the principles and implementations of the disclosure.

In the drawings:

FIG. 1 shows a schematic representation of an array of nanowires according to an embodiment of the methods and systems herein disclosed.

FIG. 2 shows a schematic representation of a side elevational view of the array of FIG. 1 in a system according to an embodiment of the devices, methods and systems herein disclosed.

FIG. 3 shows steps of a method to fabricate a nanoelectronic device in accordance with an embodiment of the present disclosure.

FIGS. 4A and 4B show a diagram (FIG. 4A) and a SEM image (FIG. 4B) of a single device section containing three groups of ˜10 SiNWs in a microfluidics channel. The wafer is covered with Si₃N₄ except for an exposed active region or window with SiNWs. The inset of FIG. 4B shows a high resolution SEM image of 20 nm SiNWs.

FIG. 5 shows two possible embodiments (Scheme 1 and Scheme 2) of the surface of the nanoscale wires in accordance with an embodiment of the present disclosure;

FIG. 6A shows an XPS (X-ray Photoelectron Spectroscopy) of a Si 2p region of Si(100) surface functionalized as in Scheme 2 of FIG. 5 before (dark grey) and after (light grey) TFA (trifluoroacetic acid) deprotection and 10 hrs in 1×SSC buffer. Nonfunctionalized Si(100) surface with native oxide (black). Inset of FIG. 6A: N 1s region of nonfunctionalized Si(100) surface (black), Si(100) functionalized by Scheme 1 (light grey) and Scheme 2 (dark grey).

FIG. 6B shows Current-Voltage (IV) graphs of SiNWs functionalized by Scheme 1 of FIG. 5 in solutions of varying pH. Inset: Solution gated (V_{SG}) n-type hydroxyl terminated SiNW in solutions of varying pH.

FIG. 7 shows a solution gating of SiNWs functionalized by Scheme 1 (light grey) and by Scheme 2 (dark gray) (V_{SD} was 50 mV). The right inset of FIG. 7 shows IV curves of SiNWs in air with (black) and without (grey) oxide. The left inset of FIG. 7 shows resistances in air of SiNWs functionalized by Scheme 1 (left) and Scheme 2 (right).

FIG. 8 shows a real-time response of SiNWs functionalized as in Scheme 1 to the addition of (a) 10 μM ssDNA and (b) 100 nM complementary DNA. The right top inset of FIG. 8 shows a real-time SiNW response to the sequential addition of (a) 0.165M SSC, (b) 0.0165M SSC, and (c) 0.00165M SSC buffers. The left inset of FIG. 8 shows SPR (surface plasmon resonance) measurement showing the addition of 10 μM ssDNA to poly-L-lysine coated CM5 sensor chip. V_{SD}=50 mV.

FIGS. 9A-9D show concentration-dependent, real-time sensing of complementary DNA by SiNWs and by SPR in 0.165M electrolyte.

FIG. 9A shows real-time responses of SiNWs that were surface functionalized according to Scheme 1 of FIG. 5 and coated with electrostatically adsorbed primary DNA. The black trace represents exposure of the SiNW sensors to 100 nM non-complementary ssDNA. Each curve represents measurements from a different set of NWs. The inset of FIG. 9A shows a fluorescence image of a Si(100) surface (with overlaying PDMS microfluidics chip) treated as in Scheme 1 of FIG. 5 followed by 10 μM primary DNA addition and addition of (microchannel a) 100 nM noncomplementary fluorescent DNA and (microchannel b) 100 nM complementary fluorescent DNA. The PDMS microfluidic chip was removed before the image was collected.

FIG. 9B is similar to FIG. 9A, except the SiNWs were functionalized according to Scheme 2 of FIG. 5. The inset of FIG. 9B is the same as the inset of FIG. 9A, but the Si(100) surface was treated as in Scheme 2 of FIG. 5.

FIG. 9C shows a SPR measurement of the hybridization of complementary DNA to electrostatically adsorbed primary, DNA on a poly-L-lysine surface.

FIG. 9D shows normalized SINW responses for FIG. 5 Scheme 1 (black dots) and Scheme 2 (grey dots) surface preparations, as a function of the log of DNA concentration. For all measurements, V_{SD}=50 mV.

FIG. 10 shows a comparison of SPR-derived hybridization kinetic parameters with NW sensing data. The black line represents eq. 5 plotted using kₒₙ and k_{off} obtained from SPR measurements, β=(kₒₙC+k_{off})t. The grey trace is obtained from SiNW resistance versus time data,

$$β = \frac{Δ R}{{R}_{max} - R} \cdot C = 10 nM .$$

FIG. 11 shows a schematic illustration of a method for the fabrication and assembly of a two-layer PDMS chip for solution injection (top) with a sensing device composed of SOI wafer and a single-layer PDMS chip with six separate microchannels (bottom)

### DETAILED DESCRIPTION

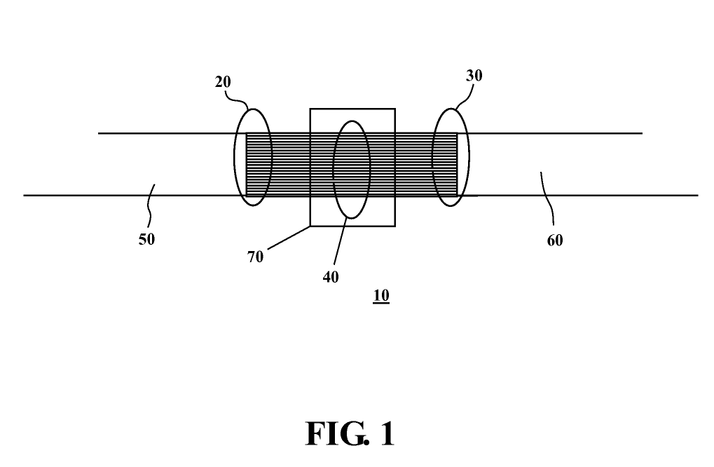

FIG. 1 is a schematic representation showing an array (10) of doped nanowires (e.g., silicon nanowires) coated with a probe biomolecule along a substantially central region (40) thereof. The nanowires of the array (10) also comprise end regions (20, 30), electrically contacted to a first metal contact (50) and a second metal contact (60). Differently from the central regions (40), the end regions (20, 30) are covered with an insulating material. Element (70) of FIG. 1 shows a window (70) for the actual sensing area of the device and method in accordance with this disclosure. In particular, the window (70) is the region of the nanowires not covered with an insulating material. In this way, the region (70) will be exposed to the solution that will later flow through the nanowires. Coating (40) of the nanowires will occur inside the window (70). The size of the window (70) and the extension of the coating (40) will define the size of the active sensing area.

The structure of the nanowire array (10) is defined by the GaAs/AlGaAs wafer grown by the MBE (Molecular Beam Epitaxy) technique, as also explained in other portions of the present disclosure. The number of wires can be controlled by growing alternative layers of GaAs/AlGaAs. A possible number is 1400, and such number is just limited by the MBE.

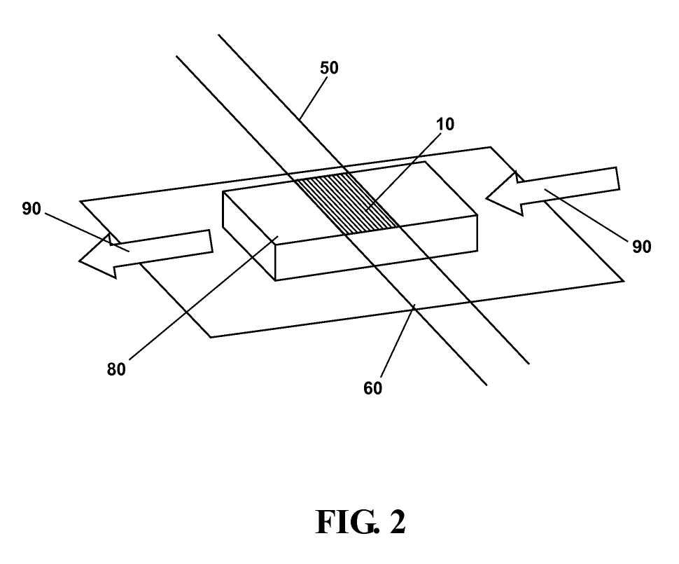

FIG. 2 shows a further schematic view, where the elements (10)-(70) previously described in FIG. 1 are placed across a microfluidic channel (80). The channel (80) will direct a flow (90) of solution containing the target molecules (e.g., biomolecules) of the present disclosure. Further features of the microfluidic channel (80) are identifiable by a skilled person upon reading of the present disclosure and therefore will not be further described herein in detail. As also explained later in greater detail, the detection mechanism according to the present disclosure is based on the charge of the target molecules. Therefore, any molecule or biomolecule that has a certain charge in the solution to be flown and proper capture agents (as later discussed in greater detail) can be flown. For example, target molecules can be DNA, RNA and proteins. Moreover, if there is any capture agent for non-bio molecules and those molecules have electrical charges, they can be used as targets, with a different surface chemistry.

Once a flow of solution containing the target molecule or biomolecule has been flown in the microfluidic channel (80), the electrical resistance of the nanoscale wires is monitored. This is done in order to record change in resistance of the nanoscale wires over time at two different values of target molecule concentration to determine both an on-rate kₒₙ and an off-rate k_{off} or target-probe binding. After this has been done, a solution containing the target molecule at an unknown molar concentration is introduced, in order to quantitatively determine the molar concentration of the target molecule or biomolecule.

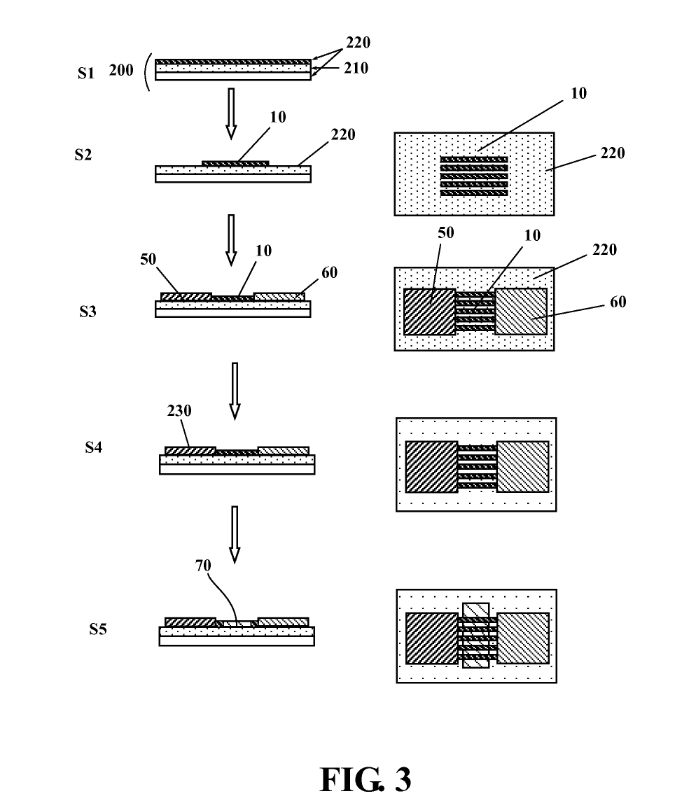

FIG. 3 shows steps of a method to fabricate the nanoelectronic device in accordance with the present disclosure. In step S1 a SOI (silicon-on-insulator) substrate (200) is provided, comprising silicon layers (210) sandwiching an insulator (e.g. SiO₂) layer (220). In step S2 nanowires (10) are made by etching the top silicon layer (210). The result of step S2 is shown both in cross-sectional and top view. In step S3, electrical contacts (50, 60) are made. In step S4, an insulating layer (230), e.g. silicon nitride, is deposited. In step S5, the insulating layer (230) is patterned to open a window (70) for the active sensing area of the nanowires (10).

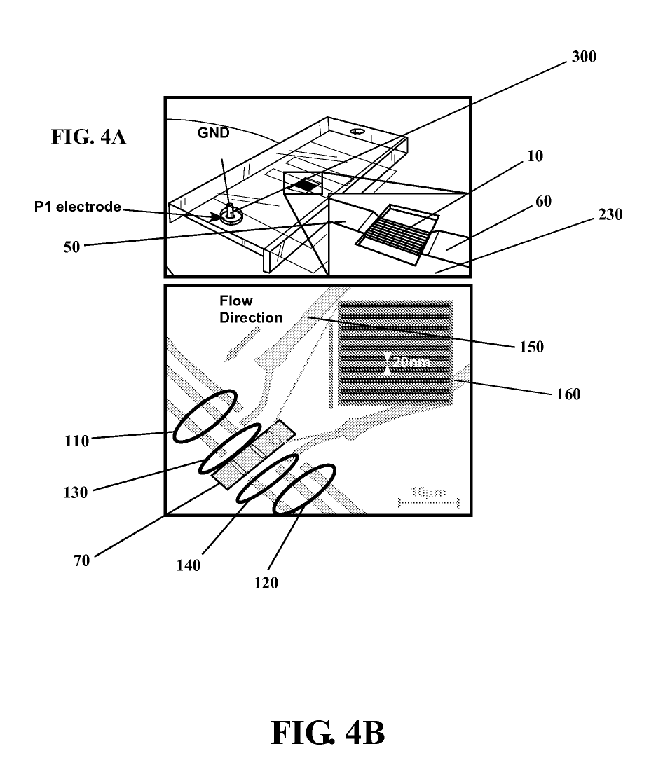

FIG. 4A shows a schematic perspective view on an embodiment of the present disclosure, where electrical contacts (50, 60) represent source/drain contacts of a transistor, as shown in the enlarged inset of the Figure. FIG. 4A also shows the microfluidics channel (80) and a platinum electrode (300) formed in a hole of the microfluidics channel (80) and connected to ground. The platinum electrode is used to ground the solution, in particular by setting the electrical potential to be identical to the ground of a lock-in amplifier used to measure the current and provide input signals. This measuring arrangement is just one of many other measuring arrangements that can be devised for use with the present disclosure. The two holes in the channel shown in the figure represent the inlet and the outlet of the microfluidic channel.

FIG. 4B shows the embodiment of FIG. 4A in enlarged scale. The rectangular aperture in the middle of FIG. 4B shows the window opening (70), together with three sets of nanowires (10), each having first metal (source/drain) contacts (110) and second metal (source/drain) contacts (120). One or more devices can be realized in a single embodiment. By way of example, FIG. 4B shows three different stripes (and devices) in a single microfluidic channel. Electric contacts (150, 160) for a four-point measurement are also shown. Those contacts are intended to check how good the electrical contacts (110, 120) and are not intended to be used during sensing. FIG. 4B also shows darker regions (130, 140). Those regions show that the nanoscale wires of the three devices of FIG. 4B can have different lengths and show nanowires covered by the insulating later, e.g., a silicon nitride layer.

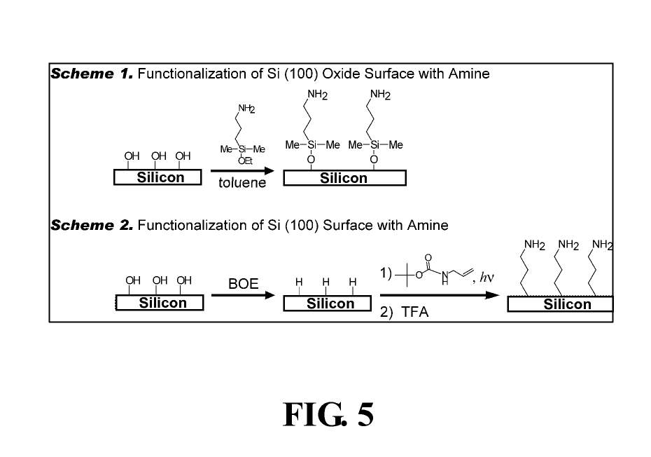

By way of example, the present disclosure shows how a quantitative, real time detection of single stranded oligonucleotides with silicon nanowires (SiNWs) in physiologically relevant electrolyte solution can be obtained. In such embodiment, Debye screening of the hybridization event is circumvented by utilizing electrostatically adsorbed primary DNA on an amine-terminated NW surface. Two surface functionalization chemistries have been compared: an amine terminated siloxane monolayer on the native SiO₂ surface of the SiNW (see Scheme 1 of FIG. 5), and an amine terminated alkyl monolayer grown directly on a hydrogen-terminated SiNW surface, as shown in Scheme 2 of FIG. 5. The SiNWs without the native oxide (Scheme 2) exhibited improved solution-gated field-effect transistor characteristics and a significantly enhanced sensitivity to single stranded DNA detection, with an accompanying two orders of magnitude improvement in the dynamic range of sensing. The applicants have developed a model for the detection of analyte by SINW sensors and utilized such model to extract DNA binding kinetic parameters kₒₙ and k_{off}. Those values have also been directly compared with values obtained by the standard method of surface plasmon resonance (SPR), and shown to be similar. The nanowires, however, are characterized by higher detection sensitivity. The implication is that Si NWs can be utilized to quantitate the solution phase concentration of biomolecules at low concentrations. This disclosure also shows the importance of surface chemistry for optimizing biomolecular sensing with silicon nanowires. Additional material suitable for the manufacturing of nanowires for the devices, methods and systems according to the present disclosure are identifiable by the skilled person upon reading of the present disclosure and will not be further described herein in detail.

The applicants used contact angle measurements to follow the functionalization processes of various surfaces (Table 1). The procedure in Scheme 1 of FIG. 5 (where the doped silicon nanowires have a SiO₂ surface) generates a large increase in contact angle. Similarly, large changes in contact angles are observed for photochemically treated Si surface before and after t-Boc deprotection. In Scheme 2 of FIG. 5, the doped silicon nanowires have a hydrogen-terminated surface. The resulting contact angle of ˜60° is observed for surfaces prepared by Schemes 1 and 2 of FIG. 5, arguing for an existence of chemically similar, amine terminated monolayers on these surfaces.

TABLE 1
Measured contact angles for various Si(100) surfaces.

| Si(100) surface | contact angle (deg) |
|---|---|
| With nonfunctionalized oxide | 11 ± 1 |
| Scheme 1: amine terminated | 61 ± 1 |
| Scheme 2: t-Boc protected | 81 ± 1 |
| Scheme 2: deprotected, amine terminated | 60 ± 1 |

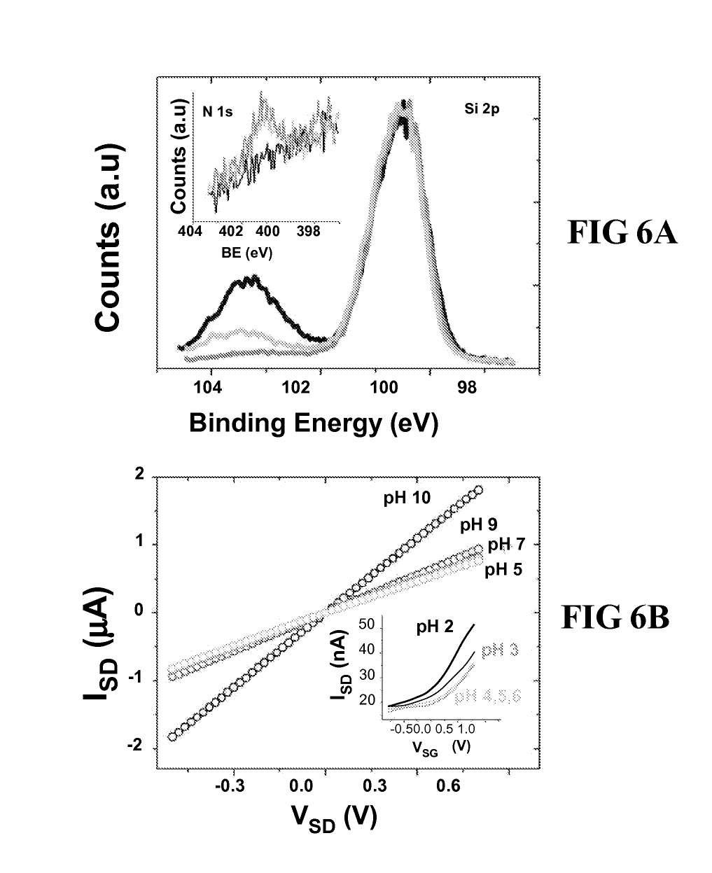

Quantifying the amount of oxide on the SOI NWs is extremely challenging. Therefore, Applicants used Si(100) bulk surfaces to approximate the amount of surface oxide remaining after photochemical functionalization. FIG. 6A shows XPS scan in the Si/SiOₓ region. The Si(100) surface with native oxide exhibited approximately 1.9 equivalent monolayers of SiOₓ. In contrast, the Si(100) surface treated according to Scheme 2 contained 0.08 equivalent monolayers of SiOₓ prior to TFA deprotection and 0.3 monolayers of SiOₓ after the deprotection step and a 10 hour exposure to 1×SSC buffer. The roughness of a SiNW surface may cause a more extensive oxidation than the one observed on the bulk surface, but the data in FIG. 6A does show a significant reduction in oxide thickness after photochemical treatment. Furthermore, applicants used XPS to determine the presence of amine terminated monolayer on bulk Si(100) surfaces post functionalization with two different schemes. The inset of FIG. 6A shows the XPS scans of N 1s regions. A Nitrogen peak is clearly visible for surfaces functionalized by Schemes 1 and 2 (FIG. 6A light gray curve and dark gray curve), while no peak is present for the nonfunctionalized Si (FIG. 6A, black curve).

Scheme 1—functionalized SiNWs shows a sensitivity to pH which is different than for native oxide-passivated NWs [Reference 45]. The isoelectric point of silica is ˜2 [Reference 46], implying that for hydroxyl terminated, non-functionalized SiNWs at low pH, the SiOH groups are largely protonated. At high pH, negative charges on SiO⁻ should deplete carriers in the n-type SiNWs, causing a decrease in IDS (inset of FIG. 6B). Above pH 4 the conductance is no longer modulated by increasing the pH, as most of the hydroxyl groups are deprotonated. When the surface is functionalized with amine (pKₐ ˜9-10), the opposite trend is expected. At low pH, the amine is protonated, causing carrier depletion or increased resistance in p-type SiNW. This trend is observed in FIG. 6B, where the sharpest transition in resistance occurs between pH 9 and 10. The observation of the correct pH effects on the resistance of the SiNWs further confirms of the presence of amine surface functional groups.

As discussed above, a hydrogen-terminated surface showed better sensitivity. However, in terms of sensing, both of the above surfaces can be utilized. The final goal of surface treatment for DNA sensing is that of making a positively charged surface, which can be done with different treatments and materials. In the examples discussed above, the applicants chose the amine because positively charged and widely used. Additional treatments of surfaces according to the present disclosure are identifiable by a skilled person and will not be further described herein in detail.

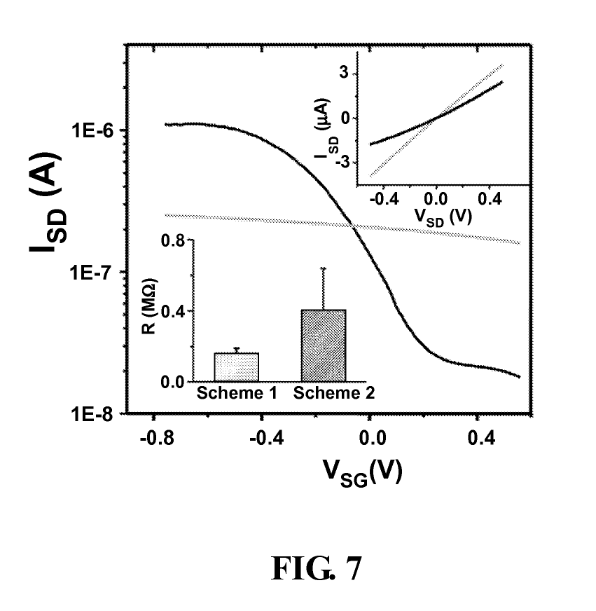

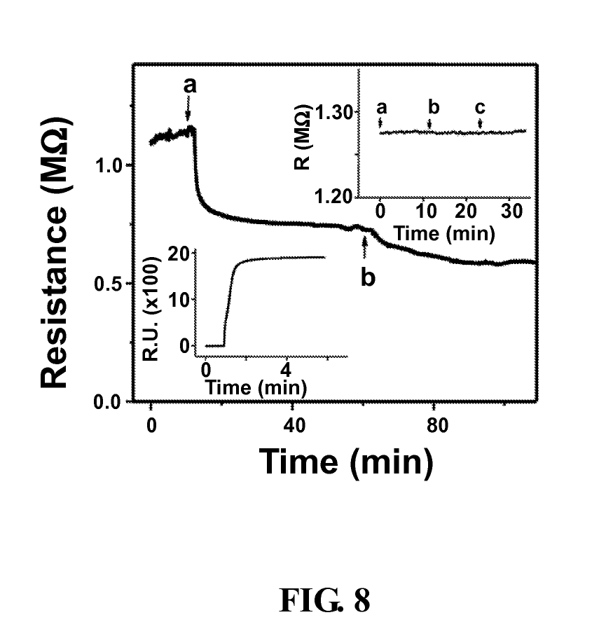

As shown in FIG. 7, oxide covered SiNWs in 1×SSC buffer (0.165M, pH 7.2) respond weakly to the applied solution gate voltage, V_{SG}, showing no significant on-off current transition between 0.8 and −0.8 Volts. In contrast, directly passivated SiNWs (Scheme 2 of FIG. 5) exhibit on-off current ratios of ˜10². FIG. 7 strongly suggests that directly passivated SiNWs exhibit an enhanced response to surface charges and should therefore serve as superior NW sensors compared with similarly functionalized, but oxide-passivated SiNWs.

The Scheme 2 procedure does involve an HF etch step, which can be potentially detrimental to the device conductance. Applicants thus checked the conductivity of SiNWs before and after photochemical treatment. Lightly doped SiNWs provide for superior FET properties [Reference 47], and, in fact, Applicants have reported that lightly doped (10¹⁷ cm⁻³) p- or n-type SiNWs are more sensitive biomolecular sensors than those discussed in the present disclosure [Reference 48]. Applicants' doping process preferentially dopes the top few nanometers of the SiNWs [Reference 49]. Thus, if the HF etching of the Si surface was extensive enough, one could expect an enhancement in SiNW current modulation by V_{SG} to be entirely due to the decrease in carrier concentration and not the removal of surface oxide. The inset of FIG. 7 show that the NW resistance increased only, on average, by a factor of 2 following the HF treatment. This relatively negligible resistance increase suggests that the major reason that the SiNWs prepared by Scheme 2 exhibit an improved solution FET performance originates from the elimination of oxide via direct silicon passivation.

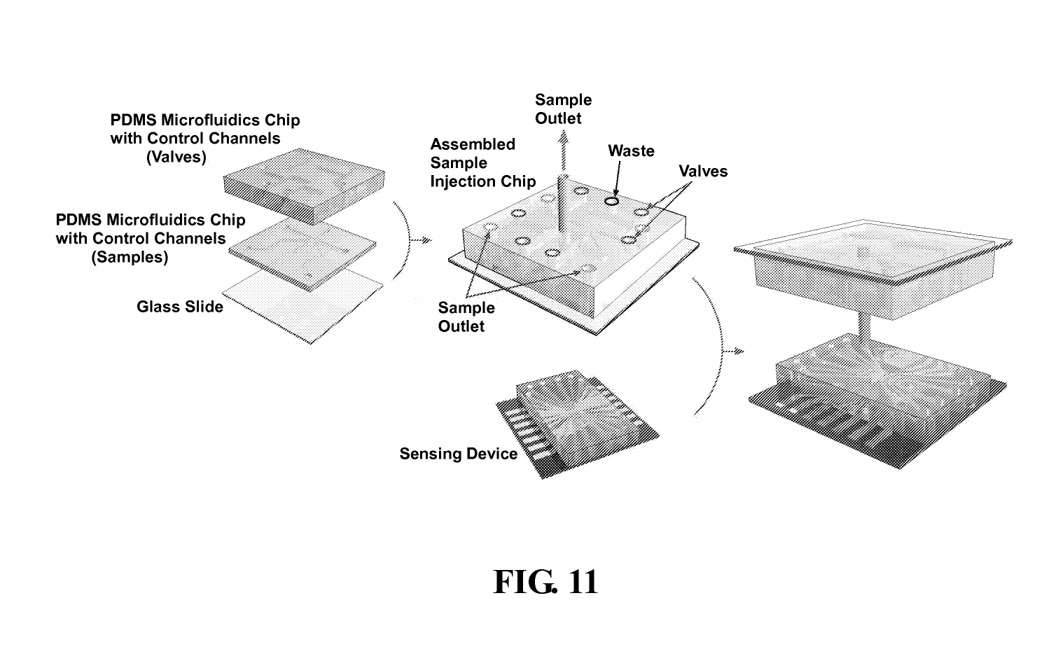

FIG. 4 shows SiNW real-time detection of the electrostatic adsorption of 10 μM ssDNA, followed by the hybridization in 1×SSC buffer of 100 nM complementary DNA strand. As expected, the resistance of p-type SiNWs is decreased with the addition of negative surface charges. The metal contacts to NWs have been covered with Si₃N₄ layer, and there is no background conductance through the solution. Applicants have observed an insignificant change in the resistance of the NWs upon switching from dry environment to buffer solution (data not shown). Moreover, as FIG. 7 (right inset) shows, changing the ionic strength of the solution does not affect the resistance. In addition, the automated solution injection (FIG. 11) removes any baseline shifts or transient changes in the resistance when solutions are switched. SPR was also utilized in parallel to SiNWs in order to validate the surface chemistry and to obtain kinetic parameters such as kₒₙ, k_{off} and affinity constant K_{A} for this particular DNA pair. Poly-L-lysine was covalently attached to the SPR sensor chips, mimicking the amine terminated monolayer of SiNWs. FIG. 7 (left inset) shows the SPR response to the electrostatic adsorption of a 10 μM primary DNA strand. The surface density of adsorbed DNA was estimated as 2.5×10¹³ cm⁻², using the conversion factor of 1000RU=100 ng cm⁻² from the literature [Reference 50]. The surface density is approximately an order of magnitude higher than the average surface density of 10¹² cm⁻² obtained when localizing biotinylated DNA on a streptavidin covered surface [Reference 52]. Such high surface density of primary DNA is expected because the poly-L-lysine treated surface is positively charged. It is likely that the amine-terminated SiNW surface has less surface charges than the poly-L-lysine covered surface and thus contains fewer sites for electrostatic adsorption of oligonucleotides.

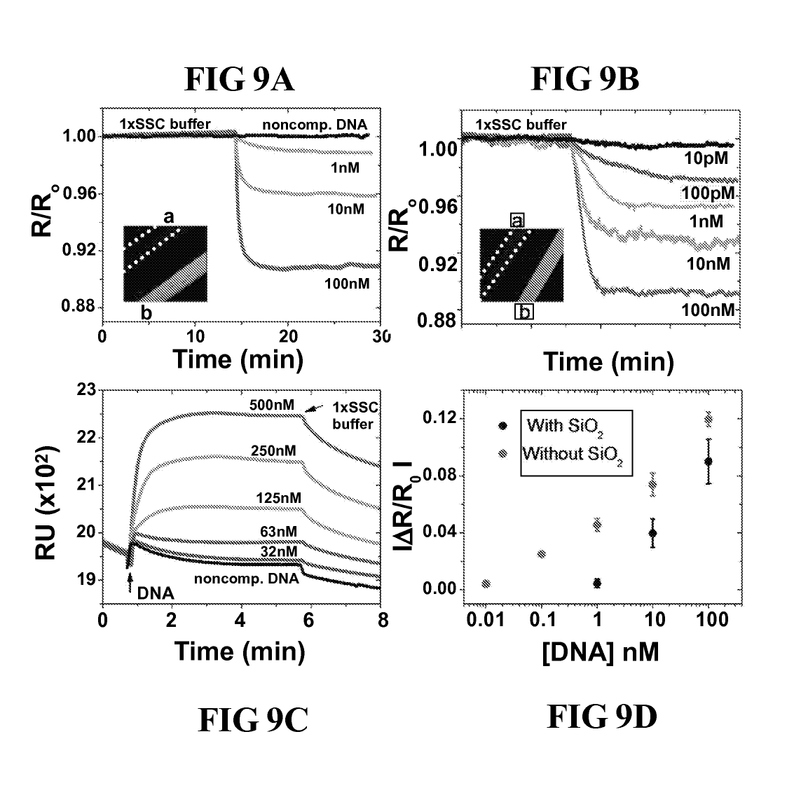

FIGS. 9A-9D show real-time label free detection of ssDNA by SiNWs and by SPR. In either case, the primary DNA strand was electrostatically immobilized on the sensor surface. Known DNA concentrations were injected after a stable reading with 1×SSC buffer was obtained and the flow was maintained throughout the experiment. Different concentrations were detected with different groups of SiNWs. Applicants observed that the hybridization on SiNWs is essentially irreversible on the relevant time scales when the analyte DNA was being washed away with the buffer solution. Such behavior is in contrast to SPR measurements, where the slow reversal of hybridization was observed (FIG. 9C). The performance of the NWs surface functionalized according to Scheme 1 (FIG. 9A) was compared to SiNW sensors prepared according to Scheme 2 (FIG. 9B). The SPR experiments, although carried out on Au substrates, also utilized primary ssDNA that was electrostatically adsorbed onto an amine terminated surface. The intention here was to find experimental conditions that could serve to validate the NW experiments by obtaining kinetic parameters for these particular DNA strands under specific experimental conditions. Control experiments with non-complementary DNA yielded no response for either SiNWs or SPR measurements (black traces of FIGS. 9A and 9C). These negative controls were also independently validated via fluorescent detection in microfluidic channels on two different (Scheme 1 and 2) Si surfaces (FIGS. 9A and 9B, insets). FIG. 9D shows that the NW response (ΔR/R₀) varies as log [DNA]. Such a logarithmic dependence has been previously reported [References 48, 53]. As shown in FIG. 9D, the dynamic range of SiNWs is increased by about 100 after the removal of oxide and UV-initiated chemical passivation; the limit of detection (LOD) increased from about 1 nM to about 10 pM.

As discussed above in the present disclosure, SiNW sensors can be utilized to quantitate analyte concentration and binding constants. In order to explore this application, the SiNW sensing response should be compared with other label-free, real-time methods such as SPR. Experimental parameters should also be designed for both sensing modalities that are as similar as possible, as was described above. In the following description, applicants first discuss the use of electrostatically adsorbed primary DNA for detecting complementary DNA analyte. Applicants then discuss the development of a self-consistent model that allows for the direct comparison of SPR measurements with nanowire sensing data. Finally, applicants test that model by utilizing the nanowire sensing data to calculate 16-mer DNA binding constants and analyte concentrations.

Previous studies have shown that the Langmuir model can be applied for parameterization of the hybridization processes of short oligonucleotides [References 19, 52]. Applicants used the Langmuir model to calculate kinetic parameters from the SPR hybridization measurements (FIG. 9C) and obtained kₒₙ=1×10⁵, k_{off}=2×10⁻², K_{A}=5×10⁶ (Table 2). This K_{A} value is between 10 and 100 times smaller than that reported for similar length DNA measured with a quartz crystal microbalance, SPR [Reference 19], and surface plasmon diffraction sensors (SPDS) [Reference 52]. The average primary DNA surface coverage in those studies was ˜5×10¹² molecules/cm² [References 19, 52]. As stated above, the electrostatically adsorbed DNA coverage in applicants' SPR experiments was approximately 10 times higher, at 2.5×10¹³ cm⁻². This difference in coverage likely arises from the differing methods of DNA immobilization; while in the applicant's embodiment the DNA is electrostatically adsorbed, other studies utilized a streptavidin-biotinylated DNA linkage for surface immobilization [References 19, 52]. High surface coverage of primary DNA significantly reduces the efficiency of hybridization [References 51, 52]. In addition, the hybridized duplex of electrostatically adsorbed and covalently bound DNA may be structurally and energetically different. It has been proposed that a preferred structural isomer of an oligonucleotide pair on a positively charged surface is a highly asymmetrical and unwound duplex [Reference 54]. It is possible that the non-helical nature of such a DNA duplex, together with steric effects associated with a highly packed surface, play major roles in the reduced affinity for the 15-mer pair used in this embodiment.

Applicants now turn toward developing a model for using nanoscale wire sensors, e.g. SiNW sensors, to quantitate complementary DNA pair binding constants, and, if those numbers are known, to determine the solution concentration of the analyte. A discussion of the kinetics of a surface binding assay, as measured within flowing microfluidics environments will now be provided. Zimmermann and coworkers modeled the kinetics of surface immunoassays in microfluidics environments [Reference 55]. Their model was based on four differential equations: the two Navier-Stokes partial differential equations, the Convection-Diffusion equation, and the ordinary differential equation resulting from the Langmuir binding model (i.e. the binding/hybridization equilibrium). A key result was that in the limit of high analyte flow speeds (>0.5 mm/sec) (which is the case for all the experiments here) the amount of analyte that is captured and ready for detection can be described by the ordinary differential equation resulting from the Langmuir binding model:

$$\frac{d {Θ}_{t}}{d t} = {k}_{on} C ( {Θ}_{max} - {Θ}_{t} ) - {k}_{off} {Θ}_{t} \qquad ( 1 )$$

Here, Θₜ=surface density of bound analyte molecules; kₒₙ=rate constant for association; k_{off}=rate constant for dissociation; C=solution concentration of analyte (a constant under flowing conditions); Θₘₐₓ=maximum number of binding sites available per surface area. Eq. (1) can be solved analytically:

$${Θ}_{t} = \frac{{k}_{on} {Θ}_{max} C}{{k}_{on} C + {k}_{off}} ( 1 - {e}^{- ( {k}_{on} C + {k}_{off} ) t} ) \qquad ( 2 )$$

The challenge is to translate from the resistance change of a SiNW sensor to the analyte concentration, C. However, the exact relationship between a measured resistance change and the surface density of bound analyte molecules is not intuitively clear. In the following, applicants will discuss the determination of the nature of that relationship.

Applicants have already shown above (FIG. 9D) that the cumulative change in SiNW sensor resistance arising from the binding of a charged analyte (ssDNA) at a concentration-dependent saturation was linearly proportional to the log [DNA], similar to what has been reported for VLS SiNW detection of prostate specific antigen (PSA) [Reference 53]. In mathematical terms, this means that as one approaches saturation for a given concentration:

$$\frac{Δ R}{{R}_{0}} = α ln C \qquad ( 3 )$$

where α is a constant, ΔR=R−R₀, R is resistance at time t, and R₀ is the resistance at t=0. At saturation levels eq. 2 reduces to

$${Θ}_{t} = \frac{{k}_{on} {Θ}_{max} C}{{k}_{on} C + {k}_{off}} = \frac{{K}_{A} {Θ}_{max} C}{{K}_{A} C + 1}$$

(where the binding affinity

$${K}_{A} = \frac{{k}_{on}}{{k}_{off}} ) .$$

In the limit where K_{A}C<<1 (which is usually the case with values of C≦10⁻⁹ and values of K_{A}<10⁸) this reduces to Θₜ=K_{A}ΘₘₐₓC. Therefore, at saturation, and with K_{A}C<<1, Θₜ scales linearly with C. From applicants' previous discussion, this implies that at saturation

$$\frac{Δ R}{{R}_{0}}$$

scales logarithmically with Θₜ (or equivalently that Θₜ is an exponential function of

$$\frac{Δ R}{{R}_{0}}$$

at saturation).

In estimating the relationship between resistance changes at all times (not just at saturation) and the surface density of bound analyte molecules at all corresponding times, applicants start by assuming the same functional relationship that we experimentally observe at saturation. Applicants also impose two boundary conditions. (1) When the measured resistance reaches its saturation level one would expect the maximum number of binding events to have taken place and for that number to be consistent with the prediction from the Langmuir binding model (eq. 2). (2) When the measured resistance is unchanged from its starting level one expects zero binding events (again consistent with the Langmuir model at time=0). Based on these assumptions and boundary conditions one can thus estimate that the surface density of bound analyte molecules as a function of resistance change has the form:

$${Θ}_{t} = \frac{{k}_{on} {Θ}_{max} C}{{k}_{on} C + {k}_{off}} ( 1 - {e}^{\frac{- Δ R}{{R}_{max} - R}} ) ; ( {R}_{max} = R at saturation ) . \qquad ( 4 )$$

The validity of eq. 4 can be tested by considering the following expression that is derived from eq. 4 and comparing it to the same expression derived from eq. 2:

$$\frac{{Θ}_{t}}{\frac{{k}_{on} {Θ}_{max} C}{{k}_{on} C + {k}_{off}}} = [ 1 - {e}^{\frac{- Δ R}{{R}_{max} - R}} ] = [ 1 - {e}^{- ( {k}_{on} C + {k}_{off} ) t} ] \qquad ( 5 )$$

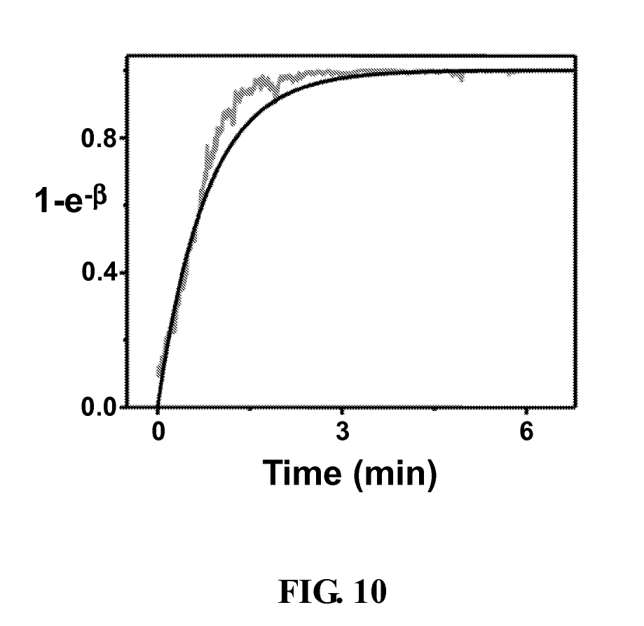

Note that eq. 5 is expressing the fraction of bound analyte molecules at time t relative to the level at saturation in terms of ΔR (first term in brackets) and in terms of binding constants (second term in brackets). Time appears explicitly in the second term in brackets, while it is implicit in the first term in brackets (i.e., at a given time t there is a given R and ΔR). If one plots the first term in brackets in eq. 5 (the term containing ΔR) against the second term in brackets (using kₒₙ and k_{off} values from an SPR analysis), one finds that the two curves are similar (FIG. 10).

A second test of eq. 4 is t6 utilize it to extract binding kinetics. As one can infer from eq. 5, if eq. 4 is equivalent to the Langmuir binding model (eq. 2), then:

$$\frac{Δ R}{{R}_{max} - R} = ( {k}_{on} C + {k}_{off} ) t \qquad ( 6 )$$

kₒₙ and k_{off} values can thus be extracted from measured resistance data. R versus time traces can be selected at any two concentration values. Taking R and ΔR at an arbitrary point in time and noting Rₘₐₓ (the resistance at saturation), two equations (one for each concentration C) and two unknowns are obtained. One can thus solve for kₒₙ and k_{off} and compare directly with kinetic parameters obtained from SPR experiments. The kₒₙ, k_{off}, and K_{A} values are summarized in Table 2. The kₒₙ constants determined from the SiNW experiments are 3-5 times larger than kₒₙ obtained with SPR experiments. The nanowire-measured k_{off} values, however, are consistently quite close to those measured with SPR. As stated above, the variation in kₒₙ values may be a reflection of steric affects that arise from the unusually high surface density of primary DNA adsorbed onto the poly-L-lysine surfaces that were used for the SPR experiments [References 51, 52].

Table 2 shows kinetic parameters estimated from SiNW biosensors for the hybridization of 16-mer DNA and corresponding comparisons with analogous SPR and SPDS (surface plasmon diffraction sensor) [Reference 52]. The calculated concentrations (bottom row) were estimated with eq. 6, by using the pair of SiNW measurements that did not include the concentration to be determined. For example, the 1 nM and 100 nM measurements were used to determine the concentration at about 10 nM. Standard deviations are given in parentheses.

TABLE 2

| | | | | SPR (this work) | SPDS (ref. 52) |
|---|---|---|---|---|---|
| | SiNWs: concentration pair: | | | (poly-L-lysine | (avidin-biotin |
| | 10 nM | 1 nM | 1 nM | surface, 16-mer | linkage, |
| | 100 nM | 100 nM | 10 nM | DNA) | 15-mer DNA) |
| kₒₙ(M⁻¹s⁻¹) | 3.5(3.4) × 10⁵ | 4.2(2.4) × 10⁵ | 6.2(9.6) × 10⁵ | 1.01 × 10⁵ | 6.58 × 10⁴ |
| k_{off}(s⁻¹) | 3.1(0.5) × 10⁻² | 2.4(0.8) × 10⁻² | 2.4(0.9) × 10⁻² | 2.01 × 10⁻² | 1.32 × 10⁻⁴ |
| K_{A}(M⁻¹) | 1.1 × 10⁷ | 1.8 × 10⁷ | 2.6 × 10⁷ | 5.02 × 10⁶ | 4.98 × 10⁸ |

| | |
|---|---|
| [DNA] | 100 nM (actual); 68(52) nM calculated. |
| | 10 nM (actual); 14(9) nM calculated |

With these resistance data useful binding kinetics can be extracted. The most useful application of the applicants' model would be in extracting otherwise unknown concentration values once kₒₙ and k_{off} values are known. The present disclosure shows embodiments where SiNW sensors can be used for label-free biomolecule detection at concentrations significantly below the limits of detection for SPR. Thus, the potential for SiNW sensors to quantitate analyte concentrations when the concentrations are below 10 nM represents a nontrivial application. The consistency of the SiNW measurements that is reflected in the Table 2 values is worth noting, especially since each measurement was carried out using a different SiNW sensor. This provides validation that the nanofabrication techniques that were utilized to prepare the NW sensing devices are highly reproducible.

Real-time label free detection of DNA 16mers with SiNWs in physiologically relevant 0.165M electrolyte solution has been shown in accordance with an embodiment of the present disclosure. In such embodiment, primary DNA was electrostatically adsorbed onto an amine terminated SiNW surface and hybridized to the complementary strand in a microfluidics channel under flow. Electrostatic adsorption of ssDNA to poly-L-lysine coated surface has previously been electronically detected at nanomolar concentrations with capacitive methods on highly doped Si electrodes in 0.015M solution [Reference 56]. The ability to detect DNA under physiological conditions, as shown in the present application, is of significance as it indicates the direct use of biological samples such as serum or tissue culture media. It is likely that because the primary DNA is electrostatically bound and hybridization occurs very close to NW surface, Debye screening does not prevent SiNW based detection. Moreover, DNA hybridization is more efficient under high ionic strength conditions [References 10, 19, 51].

SiNWs with significantly reduced oxide coverage exhibited enhanced solution FET characteristics (FIG. 7) when compared to SiNWs characterized by a native SiO₂ surface passivation. Oxide covered, highly doped SiNWs were designed to exhibit a similar dynamic range of DNA detection as the best near-infrared imaging SPR technique [Reference 57]. −10 nM for 18mer, corresponding to ˜10¹¹ molecules/cm². When identical nanowires were functionalized by the UV-initiated radical chemistry method, resulting in near-elimination of the Si—SiO₂ interface, the limit of detection was increased by two orders of magnitude, with an accompanying increase in the dynamic range. This result highlights the importance of controlling surface chemistry of SiNWs for their optimization as biological sensors. In the future, surface chemistries yielding higher coverage than UV-initiated alkylation may be utilized to passivate and electrochemically convert SiNWs into arrays for multiparameter analysis [References 58, 59].

Finally, a model that is consistent with both the standard Langmuir binding model and with the experimentally measured electrical response of SiNW sensors to the detection of complementary DNA was developed. The model yields results for an oligonucleotide pair binding affinities that are at least consistent with those measured by more standard methods such as SPR.

Further details concerning the identification of the features of the devices, models, methods and systems herein disclosed, can be identified by the person skilled in the art upon reading of the present disclosure.

### EXAMPLES

The methods and system herein disclosed are further illustrated in the following examples, which are provided by way of illustration and are not intended to be limiting.

### Si NW Fabrication

The Si NW arrays were fabricated as previously described [Reference 39] and all fabrication was done within a class 1000 or class 100 clean room environment. An embodiment of a NW sensor device employed in the present application for DNA sensing has been shown in FIGS. 4A and 4B. The starting material for the SNAP process was an intrinsic, 320 Å thick silicon-on-insulator (SOI) substrate with (100) orientation (Ibis Technology Inc., Danvers, Mass.) and with a 1500 Å buried oxide. Cleaned substrates were coated with either p-type (Boron A, Filmtronics, Inc. Bulter, Pa.) or n-type (Phosphorosilica, Emulsitone, Inc., Whippany, N.J.) spin-on-dopants (SODs). SODs were thermally diffused into the SOI film. Applicants reproducibly controlled the resulting substrate doping concentration, as quantified by 4-point resistivity measurements on the SOI film, by varying the diffusion temperature. For this study, a 3 minute, 850° C. (875° C.) rapid thermal anneal was used to generate p (n) dopant levels of ˜8×10¹⁸/cm³. The p-type substrates were thermally oxidized in O₂ for 1 minute at 850° C., which was necessary to remove the organic SOD residue. The SOD films were removed by brief immersion in piranha (70% H₂SO₄, 30% H₂O₂), followed by a water rinse, and immersion in buffered oxide etchant (BOE; General Chemical, Parcippany, N.J.).

The SNAP method for NW array fabrication translates the atomic control achievable over the individual layer thicknesses within an MBE-grown GaAs/AlₓGa₍₁₋ₓ₎As superlattice into an identical level of control over NW width, length and spacing. This method has been described in some detail elsewhere [References 26, 39] and will not be described here. Applicants utilized the SNAP process to produce a 2 mm long array of 400 SiNWs, each of 20 nm width and patterned at 35 nm pitch (FIG. 4B, inset).

The SiNWs were sectioned into ˜30 μm long segments using e-beam lithography (EBL) and SF₆ RIE etching, producing segments of ˜10 SiNWs, each with a width of 20 nm. Six identical sections, each containing 3 NW segments were produced. One such section has been shown in FIG. 4B. When fully integrated with the microfluidics channels, this allowed for six separate measurements, with three independent NW segments per measurement. Source (S) and drain (D) electrical contacts, ˜500 nm wide and separated by 10-15 μm, were patterned using electron beam lithography (EBL) on each section of SiNWs. Prior to metallization, the native oxide of the SiNWs over the contacts was removed with BOE to promote the formation of ohmic contacts. Finally, 400 Å Ti and 500 Å Pt were evaporated to form S/D contacts.

Immediately after the lift-off, the devices were annealed in 95% N₂, 5% H₂ at 475° C. for 5 minutes. This step greatly improves the characteristics of SNAP SiNW FETs. To provide room for a 1 cm by 1.5 cm PDMS chip with microchannels for analyte delivery to each section of the SiNWs (FIG. 4A), the electrical contacts were extended to the edges of the substrate using standard photolithography techniques followed by evaporation of 200 Å Ti and 1500 Å Au. To eliminate parasitic current between metal contacts in solution, approximately 70 nm Of Si₃N₄ was deposited using plasma-enhanced chemical vapor deposition (PECVD) everywhere on the chip except in 5 μm by 20 μm window regions over the NWs and the outer tips of the Au contacts.

Briefly, 100 nm of chromium was deposited over an active region of the NWs. PECVD was used to deposit Si₃N₄ film at 300° C. (900 mT, 20 W, 13.5 MHz) from N₂ (1960 sccm), NH₃ (55 sccm) and SiH₄ (40 sccm) gases. The nitride film was selectively etched with CHF₃/O₂ plasma over the protected NW region using PMMA as a mask, followed by the removal of chromium with CR-7C (Cyantek Corp., Fremont, Calif.).

### Microfluidics Fabrication

The soft lithography microfluidics chips were fabricated as described by others [Reference 40]. Applicants observed that manual introduction/changing of solutions caused serious noise, capacitive currents and baseline shifts in real-time recordings. Thus, for low noise, stable real-time electronic measurements, Applicants found it necessary to automate fluid injection and solution switching by using PDMS multilayer, integrated elastomeric microfluidics chips of the type developed by the Quake and Scherer groups [Reference 41]. The size of the wafer containing SiNWs did not permit the inclusion of all necessary flow and control lines necessary for the fluidic handling chip, and so that was fabricated as a separate chip.

To deliver the analyte to individual sections of SiNWs Applicants designed a microfluidics chip with six separate microchannels (FIG. 11). Such PDMS chip was fabricated using a standard photolithography: mixed PDMS (Dow Corning, Inc., Midland, Mich.) was applied over a pre-made photoresist molding bn silicon wafer and incompletely cured at 80° C. for 30 minutes. The chip containing microchannels was cut out of the PDMS layer and 0.5 mm diameter holes were punctured to serve as microchannel inlets and outlets. The fluidic chip and the device containing SiNWs were then brought into contact, with the 100 μm wide microchannels aligned over the individual nanowire sections. The assembled device was cured to completion overnight at 80° C.

To automate an injection/changing of analyte solutions, Applicants also introduced a second PDMS chip which can sequentially inject four different solutions into one of six microchannels on silicon wafer. Such sample injection chip is composed of two layers, control layer and flow layer (FIG. 11). To fabricate the flow layer, mixed PDMS was spin coated on a photoresist mold at 2500 rpm for 50 sec and incompletely cured at 80° C. for 30 minutes. Control layer was fabricated by applying mixed PDMS over a photoresist mold directly and incompletely curing at 80° C., followed by the puncturing of holes for inlets and outlets. The two layers were aligned together and the inlets/outlets for the flow layer were created. After two hours at 80° C., the two-layer PDMS chip was bonded to a glass slide utilizing an O₂ plasma treatment. By utilizing such sample injection chip, applicants were able to control the injection and solution changing processes without disturbing the measurement, while maintaining the sensing device in an electrically isolated chamber at all times. By introducing a waste outlet into the sample injection chip, applicants were able to remove any bubbles arising from switching between different solutions, which also helped in maintaining a stable baseline reading. [References 6 and 38]

### Synthesis of tert-Butyl allylcarbamate

To a solution of allylamine (2.27 g, 39.8 mmol) in THF (20 ml) was added N,N-diisopropylethylamine (13 ml, 80.0 mmol) followed by di-tert-butyl dicarbonate (8.7 g, 39.9 mmol). After 1 hr, the organic solvent was evaporated under reduced pressure, and the residue was purified by silica gel chromatography, (Hex EtOAc=9:1) to give 6.6 g (93%) of a product as a clear oil. ¹H NMR 300 MHz (CDCl₃) δ 5.82 (m, 1H), 5.12 (m, 2H), 3.74 (bm, 2H), 1.45 (s, 9H).

### Surface Functionalization

The two procedures used to functionalize SiNWs with and without oxide layer are shown in Schemes 1 and 2, respectively. Both procedures resulted in an amine terminated organic monolayer atop SiN Ws. For the oxide surface functionalization, cleaned SiNWs were treated with 2% (v/v) 3-aminopropyldimethylethoxysilane (Gelest, Inc., Morrisville, Pa.) in toluene for 2 hrs. The wafers were then rinsed in toluene and methanol and incubated at 100° C. for 1 hr.

A procedure described previously in [References 37, 42] was used to functionalize hydrogen terminated SiNWs with tert-Butyl allylcarbamate (Scheme 2). SiNWs were immersed in 2% HF solution for 3 seconds, washed with Millipore water and blow dried under N₂ stream. The wafer was immediately placed in a custom made quartz container which was then pumped down to ˜2×10⁻⁵ Torr, followed by an argon purge. Under positive argon pressure, a mixture of 1:2 tert-Butyl allylcarbamate:methanol (v/v) was applied to the wafer, completely covering the SiNWs. The wafer was illuminated with UV (254 nm, 9 mW/cm² at 10 cm) for 3 hours. SiNWs were then rinsed in methylene chloride and methanol. The deprotection of t-Boc amine was carried out in a solution of TFA in methanol (1:4 v/v) for 4 hours, followed by extensive methanol washing.

### X-Ray Photoelectron Spectroscopy

X-ray photoelectron spectroscopy (XPS) was utilized to quantify the amount of oxide on Si (100) wafers after surface treatments outlined in Schemes 1 and 2. All XPS measurements were performed in an ultrahigh vacuum chamber of an M-probe surface spectrometer that has been previously described [Reference 43]. Experiments were performed at room temperature, with 1486.6 eV X-ray from the Al Kα line and a 35° incident angle measured from the sample surface. ESCA-2000 software was used to collect the data. An approach described elsewhere [References 30, 43] was used to fit the Si 2p peaks and quantify the amount of surface SiOₓ, assuming that the oxide layer was very thin. Any peak between 100 eV and 104 eV was assigned to Si⁺—Si⁴⁺ and fitted as described in the literature [Reference 44]. SiOₓ:Si 2p peak ratio was divided by a normalization constant of 0.17 for Si(100) surfaces.

### Contact Angle Measurements

The sessile contact angle of water on the functionalized Si(100) surface was used to check the fidelity of surface chemistry as described in Schemes 1 and 2. Contact angle measurements were obtained with an NRL C.A. Goniometer Model #100-00 (Rame-Hart, Inc., Netcong, N.J.) at room temperature. All measurements were repeated three times and averaged to obtain the contact angle θ for the surface.

### Surface Plasmon Resonance (SPR)

All SPR experiments were performed on the Biacore 3000 with carboxylic acid terminated Biacore CM5 chips. The active flow cells were first primed in 1×SSC (15 mM NaCltrate, 150 mM NaCl, pH 7.5). To generate an amine surface, the carboxylic acid groups were converted to succinimide esters by flowing EDC/NHS prior to exposure of a 1 mg/ml solution of polylysine (Sigma-Aldrich, St. Louis, Mo.). Single stranded DNA (5′TGGACGCATTGCACAT3′, Midland Certified, Ind., Midland, Tex.—SEQ ID NO: 1) was electrostatically absorbed unto the polylysine matrix. Complementary DNA was then immediately introduced and allowed to hybridize to the active surface. The flow cell was regenerated with two 1 minute pulses of 50 mM NaOH, after which ssDNA was reabsorbed electrostatically before another cDNA pulse was introduced for hybridization.

### Electronic Measurements

The 4-point resistivity of silicon film as well as SiNW resistances and solution gating were measured with Keithley 2400 Source Meter (Keithley Instruments, Inc., Cleveland, Ohio). The sensing experiments were performed with SR830DSP Lock-in Amplifier (Stanford Research Systems, Inc., Sunnyvale, Calif.). A 50 mVrms at 13 Hz voltage source (V_{SD}) was applied to one terminal of the nanowire, with the amplifier input operating in the current-measure mode. A platinum wire was inserted into the microchannel and used as a solution gate, while it was kept at a ground potential throughout the real-time measurements to reduce the noise in the system (FIG. 4A). The devices were functionalized and assembled as described above. Single stranded 10 μM DNA (same as in SPR experiments) in 1×SSC buffer was flowed through the microchannel for 1 hr and allowed to electrostatically adsorb to the amine terminated surface of SiNWs. The non-bound DNA was washed thoroughly with 1×SSC buffer. Complementary DNA (5′ATGTGCAATGCGTCCA3′, Midland Certified, Ind., Midland, Tex.—SEQ ID NO: 2) of varying concentrations in 1×SSC buffer was sequentially injected from the injection PDMS chip (Supplementary Material) into the microchannel containing Si NWs at a flow rate of 2.0 μl/min as the resistance of the NWs was recorded in real time. Non-complementary DNA (noncomp. DNA) (5′CATGCATGATGTCACG3′—SEQ ID NO: 3) was used as a control. In general, a different SiNW sensor was utilized for each individual measurement described in the present disclosure.

### Determination of Kinetic Parameters and Concentrations

To extract kₒₙ and k_{off} values from the resistance versus time data, applicants used equation 6 to create a series of two equation pairs with two unknowns (one equation from each concentration) which applicants solved to get the implied kₒₙ and k_{off}. For each concentration in the pair applicants chose to use all data points starting at a time where our model (the first term in brackets in equation 5) indicated a value of 0.63 (i.e., a time equal to the characteristic time of this exponential function) and ending 150 seconds later (time close to saturation, i.e., a value of 1 for eq. 5). Applicants chose this part of the data because the assumptions underlying the model indicate that values close to saturation are the ones where our model fits real data the best. For each concentration pair applicants, therefore, had 150 pairs of equations, each yielding a value for kₒₙ and k_{off}.

To extract the implied concentration values from the resistance versus time data, applicants used equation 6, this time with kₒₙ and k_{off} values obtained from a concentration pair that did not contain the concentration applicants were trying to estimate. Again, applicants chose 150 data points from the same portion of the graph used to extract kₒₙ and k_{off} values. Each data point yielded one equation in one unknown, which applicants solved to get the implied concentrations. Applicants then calculated the average implied concentration and the standard deviation for all 150 data points (results summarized in Table 2).

The examples set forth above are provided to give those of ordinary skill in the art a complete disclosure and description of how to make and use the embodiments of the devices, systems and methods of the disclosure, and are not intended to limit the scope of what the inventors regard as their disclosure. Modifications of the above-described modes for carrying out the disclosure that are obvious to persons of skill in the art are intended to be within the scope of the following claims. All patents and publications mentioned in the specification are indicative of the levels of skill of those skilled in the art to which the disclosure pertains. All references cited in this disclosure are incorporated by reference to the same extent as if each reference had been incorporated by reference in its entirety individually.

The entire disclosure of each document cited (including patents, patent applications, journal articles, abstracts, laboratory manuals, books, or other disclosures) in the Background, Detailed Description, and Examples is hereby incorporated herein by reference. Further, the hard copy of the sequence listing submitted herewith and the corresponding computer readable form are both incorporated herein by reference in their entireties.

It is to be understood that the disclosures are not limited to particular compositions or biological systems, which can, of course, vary. It is also to be understood that the terminology used herein is for the purpose of describing particular embodiments only, and is not intended to be limiting. As used in this specification and the appended claims, the singular forms “a,” “an,” and “the” include plural referents unless the content clearly dictates otherwise. The term “plurality” includes two or more referents unless the content clearly dictates otherwise. Unless defined otherwise, all technical and scientific terms used herein have the same meaning as commonly understood by one of ordinary skill in the art to which the disclosure pertains. Although any methods and materials similar or equivalent to those described herein can be used in the practice for testing of the specific examples of appropriate materials and methods are described herein.

A number of embodiments of the disclosure have been described. Nevertheless, it will be understood that various modifications may be made without departing from the spirit and scope of the present disclosure. Accordingly, other embodiments are within the scope of the following claims.

### REFERENCES

(1) Kong, J.; Franklin, N. R.; Zhou, C. W.; Chapline, M. G.; Peng, S.; Cho, K. J.; Dai, H. Science 2000, 287, 622.
(2) Patolsky, F.; Lieber, C. M. Mater. Today 2005, 8, 20.
(3) Park, S. J.; Taton, T. A.; Mirkin, C. A Science 2002, 295, 1503.
(4) Ziegler, C. Analytical and Bioanalytical Chemistry 2004, 379, 946.
(5) Lasseter, T. L.; Cai, W.; Hamers, R. J. Analyst 2004, 129, 3.
(6) Davidson, E. H., et al. Science 2002, 295, 1669.
(7) Kitano, H. Science 2002, 295, 1662.
(8) Hood, L.; Heath, J. R.; Phelps, M. E.; Lin, B. Science. 2004, 306, 640.
(9) Chen, R. J.; Bangsaruntip, S.; Drouvalakis, K. A.; Kam, N. W. S.; Shim, M.; Li, Y.; Kim, W.; Utz, P. J.; Dai, H. Proc. Natl. Acad. Sci. U.S.A. 2003, 100, 4984.
(10) Star, A.; Tu, E.; Niemann, J.; Gabriel, J.-C. P.; Joiner, S.; Valcke, C. Proc. Nat. Acad. Sci. USA 2006, 103, 921.
(11) Besteman, K.; Lee, J.; Wiertz, F. G. M.; Heering, H. A.; Dekker, C. Nano Lett. 2003, 3, 727.
(12) Hahm, J.; Lieber, C. M. Nano Lett. 2004, 4, 51.
(13) Li, Z.; Chen, Y.; Li, X.; Kamins, T. I.; Nauka, K.; Williams, R. S. Nano Lett. 2004, 4, 245.
(14) Li, C.; Curreli, M.; Lin, H.; Lei, B.; Ishikawa, F. N.; Datar, R.; Cote, R. J.; Thompson, M. E.; Zhou, C. J. Am. Chem. Soc. 2005, 127, 12484.
(15) Ramanathan, K.; Bangar, M. A.; Yun, M.; Chen, W.; Myung, N. V.; Mulchandani, A. J. Am. Chem. Soc. 2005, 127, 496.
(16) Lud, S. Q.; Nikolaides, M. G.; Haase, I.; Fischer, M.; Bausch, A. R. ChemPhysChem 2006, 7, 379.
(17) lsraelachvili, J. Intermolecular and Surface Forces; Academic Press: London, 1985.
(18) Zheng, G. F.; Patolsky, F.; Cui, Y.; Wang, W. U.; Lieber, C. M. Nat. Biotech. 2005, 23, 1294.
(19) Okahata, Y.; Kawase, M.; Niikura, K.; Ohtake, F.; Furusawa, H.; Ebara, Y. Anal. Chem. 1998, 70, 1288.
(20) Li, Z.; Rajendran, B.; Kamins, T. I.; Li, X.; Chen, Y.; Williams, R. S. Appl. Phys. A. 2005, 80, 1257.
(21) Vieu, C.; Carcenac, F.; Pepin, A.; Chen, Y.; Mejias, M.; Lebib, A.; Manin-Ferlazzo, L.; Couraud, L.; Launois, H. Ap. Suif Sci. 2000, 164, 111.
(22) Yang, P. D. MRS Bulletin 2005, 30, 85.
(23) Heath, J. R.; LeGoues, F. K. Chem. Phys. Lett. 1993, 208, 263.
(24) Morales, A.; Lieber, C. M. Science 1998, 279, 208.
(25) Chung, S. W.; Yu, J. Y.; Heath, J. R. Appl. Phys. Lett. 2000, 76, 2068.
(26) Melosh, N. A.; Boukai, A.; Diana, F.; Gerardot, B.; Badolato, A.; Petroff, P. M.; Heath, J. R. Science 2003, 300, 112.
(27) Beckman, R. A.; Johnston-Halperin, E.; Melosh, N. A.; Luo, Y.; Green, J. E.; Heath, J. R. J. Appl. Phys. 2004, 96, 5921.
(28) Yablanovitch, E.; Allara, D. L.; Chang, C, C.; Gmitter, T.; Bright, T. B. Phys. Rev. Lett. 1986, 57, 249.
(29) Sham, T. K.; Naftel, S. J.; Kim, P.-S. G.; Sammynaiken, R.; Tang, Y. H.; Coulthard, I.; Moewes, A.; Freeland, J. W.; Hu, Y.-F.; Lees, S. T. Phys. Rev. B 2004, 70, 045313/1.
(30) Webb, L. J.; Lewis, N. S. J. Phys. Chem. B 2003, 107, 5404.
(31) Bansal, A.; Lewis, N. S. J. Phys. Chem. B 1998, 102, 4058.
(32) Haick, H.; Hurley, P. T.; Hochbaum, A. I.; Yang, P.; Lewis, N. S. J. Am. Chem. Soc. 2006, 128, 8990.
(33) Terry, J.; Mo, R.; Wigren, C.; Cao, R. Y.; Mount, G.; Pianetta, P.; Linford, M. R.; Chidsey, C. E. D. Instrum. Methods. Phys. Res., Sect. B. 1997, 133, 94.
(34) Effenberger, F.; Gotz, G.; Bidlingmaier, B.; Wezstein, M. Angew. Chem., Int. Ed. Engl. 1998, 37, 2462.
(35) Boukherroub, R.; Wayner, D. D. M. J. Am. Chem. Soc. 1999, 121, 11513.
(36) Cicero, R. L.; Linford, M. R.; Chidsey, C. E. D. Langmuir 2000, 16, 5688.
(37) Streifer, J. A.; Kim, H.; Nichols, B. M.; Hamers, R. J. Nanotechnology 2005, 16, 1868.
(38) Jönsson, U., et al. BioTechniques 1991, 11, 620.
(39) Wang, D.; Sheriff, B. A.; Heath, J. R. Nano Lett. 2006, 6, 1096.
(40) Duffy, D. C.; McDonald, J. C.; Schueller, O. J. A.; Whitesides, G. M. Anal.-Chem. 1998, 70, 4974.
(41) Unger, M. A.; Chou, H. P.; Thorsen, T.; Scherer, A.; Quake, S. R. Science 2000, 288, 113.
(42) Bunimovich, Y. L.; Ge, G.; Beverly, K, C.; Ries, R. S.; Hood, L.; Heath, J. R. Langmuir 2004, 20, 10630.
(43) Haber, J. A.; Lewis, N. S. J. Phys. Chem. B 2002, 106, 3639.
(44) Himpsel, F. J.; McFeeley, F. R.; Taleb-Ibrahimi, A.; Yarmoff, J. A.; Hollinger, G. Phys. Rev. B 1988, 38, 6084.
(45) Cui, Y.; Wei, Q.; Park, H.; Lieber, C. M. Science 2001, 293, 1289.
(46) Hu, K.; Fan, F.; Bard, A. J.; Hillier, A. C. J. Phys. Chem. B. 1997, 101, 8298.
(47) Cui, Y.; Duan, X.; Hu, J.; Lieber, C. M. J. Phys. Chem. B. 2000, 104, 5213.
(48) Cheng, M. M.-C.; Cuda, G.; Bunimovich, Y. L.; Gaspari, M.; Heath, J. R.; Hill, H. D.; Mirkin, C. A.; Nijdam, A. J.; Terracciano, R.; Thundat, T.; Ferrari, M. Curr. Opin. Chem. Biol. 2006, 10, 11.
(49) Beckman, R.; Johnston-Halperin, E.; Luo, Y.; Green, J. E.; Heath, J. R. Science 2005, 310, 465.
(50) Stenberg, E.; Persson, B.; Roos, H.; Urbaniczky, C. J. Colloid Interface Sci. 1991, 143, 513
(51) Peterson, A. W.; Heaton, R. J.; Georgiadis, R. M. Nucleic Acids Res. 2001, 29, 5163.
(52) Yu, F.; Yao, D.; Knoll, W. Nucleic Acids Res. 2004, 32, e75.
(53) Zheng, G.; Patolsky, F.; Cui, Y.; Wang, W. U.; Lieber, C. M. Nat. Biotech. 2005, 23, 1294.
(54) Lemeshko, S. V.; Powdrill, T.; Belosludtsev, Y. Y.; Hogan, M. Nucleic Acids Res. 2001, 29, 3051.
(55) Zimmermann, M.; Delamarche, E.; Wolf, M.; Hunziker, P. Biomed. Microdevices 2005, 7, 99.
(56) Fritz, J.; Cooper, E. B.; Gaudet, S.; Sorger, P. K.; Manalis, S. R. Proc. Nat. Acad. Sci. USA 2002, 99, 14142.
(57) Nelson, B. P.; Grimsrud, T. E.; Liles, M. R.; Goodman, R. M.; Corn, R. M. Anal. Chem. 2001, 73, 1.
(58) Nemanick, E. J. Chemical and Electrical Passivation of Single Crystal Silicon Surfaces through Covalently Bound Organic Monolayers; Caltech Ph.D. Thesis, 2005.
(59) Rohde, R. D.; Agnew, H. D.; Yeo, W.-S.; Bailey, R. C.; Heath, J. R. J. Am. Chem. Soc. 2006, 128, 9518.

What is claimed is:

1. An electronic device for detecting target molecules, comprising:
an array of nanowires serving as sensors of target molecules, the nanowires comprising i) electrically contacted regions at their ends, the electrically contacted regions being covered with an insulating material and ii) a central window region coated with a probe molecule; and
a microfluidics channel placed across the array of silicon nanowires, the microfluidics channel adapted to direct a flow of solution containing the target molecules.

2. The electronic device of claim 1, wherein the nanowires are doped nanowires.

3. The electronic device of claim 2, wherein a doping level of the doped nanowires is selected to determine sensitivity limits and concentration ranges over which the nanowires operate.

4. The electronic device of claim 1, wherein the molecules are biomolecules.

5. The electronic device of claim 4, wherein the biomolecules are selected from the group consisting of DNA, RNA and protein.

6. The electronic device of claim 1, wherein the nanowires are doped silicon nanowires.

7. The electronic device of claim 6, wherein the doped silicon nanowires comprise an amine terminated surface.

8. The electronic device of claim 4, wherein the target biomolecules are single stranded oligonucleotides.

9. The electronic device of claim 6, wherein the doped silicon nanowires comprise a positively charged surface.

10. The electronic device of claim 9, wherein the positively charged surface is an amine-terminated surface.

11. The electronic device of claim 1, wherein the electrically contacted regions of the nanoscale wires are contacted to first and second metal contacts.

12. The electronic device of claim 11, wherein the first and second metal contacts are source and drain contacts of a transistor, respectively.

13. A method for quantitatively determine molar concentration of a target molecule, comprising:
providing an array of nanowires;
electrically contacting the nanowires at their ends;
depositing an insulating layer over the nanowires;
forming a window in the insulating layer along a region of the nanowires different from an electrically contacted region of the nanowires;
treating the surface of the nanowires for later contact with probe molecules along the region different from an electrically contacted region;
placing a microfluidic channel across the array of nanowires;
introducing a solution containing the probe molecules into the microfluidic channel, the solution reacting with the treated surface of the nanowires;
directing a flow of solution containing the target molecule in the microfluidic channel;
monitoring electrical resistance of the nanoscale wires to record change in resistance of the nanoscale wires over time at two different values of target molecule concentration to determine an on rate kₒₙ and an off rate k_{off} of target-probe binding; and
introducing a solution containing the target molecule at an unknown molar concentration to quantitatively determine the molar concentration of the target molecule.

14. The method of claim 13, wherein the nanowires are doped nanowires.

15. The method of claim 14, wherein a doping level of the doped nanowires is selected to determine sensitivity limits and concentration ranges over which the nanowires operate.

16. The method of claim 13, wherein the molecules are biomolecules.

17. The method of claim 16, wherein the biomolecules are selected from the group consisting of DNA, RNA and protein.

18. The method of claim 13, wherein the nanowires are doped silicon nanowires.

19. The method of claim 18, wherein the doped silicon nanowires comprise an amine terminated surface.

20. The method of claim 16, wherein the target biomolecules are single stranded oligonucleotides.

21. The method of claim 18, wherein the doped silicon nanowires comprise a positively charged surface.

22. The method of claim 21, wherein the positively charged surface is an amine-terminated surface.

23. The method of claim 13, wherein the electrically contacted regions of the nanoscale wires are contacted to first and second metal contacts.

24. The method of claim 23, wherein the first and second metal contacts are source and drain contacts of a transistor, respectively.

25. A method of fabricating a nanoelectronic device, comprising:
providing a silicon-on-insulator substrate;
patterning a top silicon layer of the silicon-on-insulator substrate to obtain nanoscale wires;
adding electrical contacts to the nanoscale wires;
depositing an insulating layer on the nanoscale wires and the electrical contacts; and
opening a window in the insulating layer to define a sensing area of the nanoscale wires.

26. The method of claim 25, further comprising:
coating the sensing area of the nanoscale wires with a probe molecule.

27. A nanoelectronic device for detecting target molecules, comprising:
an array of nanoscale wires serving as sensors of target molecules;
electrical contacts, electrically contacting the nanowires at end regions of the nanoscale wires;
an insulating material covering the end regions of the nanoscale wires and defining a window region of the nanoscale wires, the window region of the nanoscale wires not being covered by the insulating material; and
probe molecules, located on the nanoscale wires along the window region.


SEQUENCE LISTING (3 sequences)

SEQ ID NO: 1 - DNA, 16 bp, Artificial Sequence
  Single stranded synthetic oligonucleotide
tggacgcattgcacat

SEQ ID NO: 2 - DNA, 16 bp, Artificial Sequence
  Single stranded synthetic oligonucleotide
atgtgcaatgcgtcca

SEQ ID NO: 3 - DNA, 16 bp, Artificial Sequence
  Single stranded synthetic oligonucleotide
catgcatgatgtcacg